(19) United States
(12) Patent Application Publication
(10) Pub. No.: US 2007/0275540 A1
(43) Pub. Date: Nov. 29, 2007

(54) Backside via formation prior to die attachment

(76) Inventors: Dale A. Hackitt, Mesa, AZ (US); Dingying Xu, Chandler, AZ (US); Salvatore A. Ruggero, Chandler, AZ (US); Chan H. Yoo, San Jose, CA (US)

Correspondence Address: SCHWABE, WILLIAMSON & WYATT, P.C., PACWEST CENTER, SUITE 1900, 1211 S.W. FIFTH AVE., PORTLAND, OR, 97204, US

(21) Appl. No.: 11/440,609

(22) Filed: May 24, 2006

(51) Int. Cl. H01L 21/00

(52) U.S. Cl. 438/460

(57) ABSTRACT

Backside via formation in one or more dice prior to the one or more dice being attached to an underlying substrate is described herein. The resulting backside vias having substantially no air voids or air voids occupying not greater than 8 percent of the total volume of the backside vias.

### TECHNICAL FIELD

Embodiments of the present invention relate to the field of integrated circuits, more specifically, to methods, apparatuses, and systems associated with devices having backside vias.

### BACKGROUND

In the current state of integrated circuit technology, an integrated circuit device will often be in the form of a die. Such a die will typically be mounted onto an underlying substrate such as an underlying carrier substrate to form a “package.” Typically a package will include one or more dice that in some instances may include vias that are located on the backside surfaces of the dice, the backside surfaces being the dice surface to be coupled to or facing the underlying substrate. For example, some packages will include one or more silicon backplane (SiBP) dice having a plurality of ground (electrical ground) through silicon via (GTSV) vias located on their backside surfaces. The backside surface of the SiBP die being generally coupled to a carrier substrate such as a Copper (Cu) leadframe or a Bismaleimide-triazine (BT) substrate. The GTSV vias will typically have pyramidal or conical shapes and are typically used as, for example, electrical ground. In some packaging processes, these backside vias will be concurrently formed when the die is being attached to the underlying substrate. Unfortunately, such processes may result in the formation of unreliable backside vias.

That is, in order to form such backside vias, typically a die with a via hole (or multiple via holes) disposed on the backside, is placed over an underlying substrate. The die often includes a thin metal cap layer that is an etch stop layer placed in the die to facilitate the etching process for creating the via hole. Disposed on top of the underlying substrate typically is some conductive paste such as solder, epoxy, or other types of paste.

Attachment of the die to the underlying substrate is accomplished by pressing the die onto the conductive paste on top of the underlying substrate. The intent for pressing the die on top of the conductive paste is to fill the via hole with the conductive paste, thus electrically coupling the die to the underlying substrate. Unfortunately, by using this conventional process, an air pocket or air void may form at the top of the pyramid or conical shaped via hole resulting in a partially filled via hole. In some instances, the resulting air void may occupy from about 10 percent to about 100 percent of the total volume of the via hole. As a result of the partially filled via hole, the reliability and the electrical and thermal performance of the resulting package may be compromised.

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings.

FIGS. 1 to 3 illustrate different stages of backside via formation using a first process in accordance with various embodiments of the present invention;

FIGS. 4 and 5 illustrate different stages of backside via formation using a second process in accordance with various embodiments of the present invention;

FIGS. 6 and 7 illustrate different stages of backside via formation using a third process in accordance with various embodiments of the present invention;

FIG. 8 illustrates backside via formation using a fourth process in accordance with various embodiments of the present invention; and

FIG. 9 illustrates a system in accordance with various embodiments of the present invention.

### DETAILED DESCRIPTION OF ILLUSTRATIVE EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent.

The description may use perspective-based descriptions such as up/down, back/front, and top/bottom. Such descriptions are merely used to facilitate the discussion and are not intended to restrict the application of embodiments of the present invention.

The description may use the phrases “in various embodiments,” or “in some embodiments,” which may each refer to one or more of the same or different embodiments. Furthermore, the terms “comprising,” “including,” “having,” and the like, as used with respect to embodiments of the present invention, are synonymous.

According to various embodiments of the present invention, methods are provided that allow backside via holes of a die or dice to be filled prior to attaching the die or dice to an underlying substrate such as an underlying carrier substrate. In doing so, air voids within the backside via holes may be reduced. Employing such processes may result in the formation of semiconductor packages with dice having backside vias with air voids having volumes that are not greater than about 10 percent of the volume of the vias. In some embodiments, the air voids may be 8 percent of the volume of the vias, or less. In other embodiments, the air voids may be substantially or completely eliminated from the backside vias.

In various embodiments, the methods may include initially forming one or more via holes on a backside surface of each of a plurality of dice formed on a wafer. Conductive paste may then be deposited into the one or more via holes of each of the plurality of dice from a direction above the backside surface of each of the dice. The dice may then be singulated (i.e., separated into individual die pieces). Each of the individual dice may then be attached to one or more corresponding underlying substrates.

In various embodiments, the via holes may be pyramidal or conical shaped having a large base opening (such as about 400 μm) and a much smaller tapered top end (such as about 50 μm). In alternative embodiments, however, the via holes may have cylindrical, or other shape types. The conductive paste to be used to fill the via holes may be a solder paste, a silver epoxy paste, or other types of conductive material. In some embodiments, the dice may be SiBP dice having backside surfaces that may include GTSV vias, while the underlying substrate may be a carrier substrate such as Cu leadframe or BT substrate.

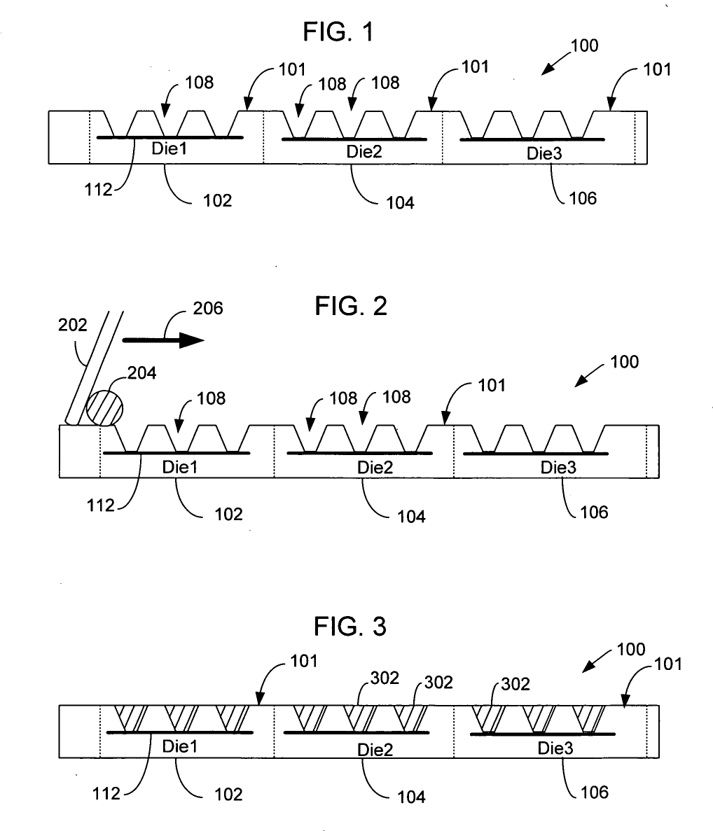

In some embodiments, a first process may be employed in which a squeegee may be used in order to fill via holes located on the backside surfaces of a die or dice prior to attaching the die or dice to their respective underlying substrates. For the embodiments, a wafer 100 is initially provided comprising multiple dice 102, 104, and 106 as depicted in FIG. 1. Each die 102, 104, and 106 includes backside surfaces 101, the backside surfaces 101 of the dice 102, 104, and 106 being the surfaces of the dice 102, 104, and 106 to be coupled with the underlying substrate(s) during subsequent die attachment operations. Note that in the following description, references may be made to the “backside surface” of the wafer 100, which is the same as the backside surfaces of the dice 102, 104, and 106. A plurality of via holes 108 is located on the backside surfaces 101 of the dice 102, 104, and 106. These via holes 108 may be formed using various techniques including chemical etching using, for example, potassium hydroxide solution. Such via holes 108 may be formed following planarization or thinning of the wafer 100. The via holes 108 may have pyramidal or conical shapes, decreasing from a wider end to a narrower end as the via holes advance through the backside surfaces 101. Again note that in alternative embodiments, the via holes 108 may have other shape types such as cylindrical or other shape types. Each of the via holes 108 may be capped at the narrower end by one or more metal cap layers 112. That is, the one or more metal cap layers 112 may be a single cap layer to cap a plurality of via holes 108 as depicted in FIG. 1 or multiple cap layers, each cap layer capping corresponding via holes.

FIG. 2 depicts the employment of a squeegee 202 on top of the backside surface 101 of the wafer 100, in accordance with various embodiments. The squeegee 202 may be used to fill the via holes 108 with a conductive paste 204 from a direction above the backside surface 101 of each of the dice 102, 104, and 106. In some embodiments, the conductive paste 204 may be in the form of a conductive paste roll. To fill the via holes 108 with the conductive paste 204, the squeegee 202 may be dragged along the backside surfaces 101 of the dice 102, 104, and 106 as indicated by reference 206 forcing the conductive paste 204 into the via holes 108. The via holes 108 may be filled without a significant amount of air space or void being trapped at the bottom of the via holes 108 as shown in FIG. 3. In some embodiments, vias 302 with air voids having a volume not greater than 10 percent of the via holes, and in some cases, 8 percent or less of the via holes may be formed on the backside surfaces 101 of the dice 102, 104, and 106.

Once the via holes 108 have been filled, several alternative approaches may be employed to dice the wafer 100 into individual die units or pieces, and to attach the individual die pieces to their corresponding underlying substrates. For example, in one approach, the backside surface 101 of the wafer 100 may be laminated with a thin film adhesive (not shown). The wafer 100 may then be diced into individual die pieces (i.e., dice 102, 104, and 106). Each of the individual die pieces may then be attached to their respective underlying substrate without adding additional conductive paste to the surface of the underlying substrate.

In another approach, a B-stage cure may be performed in order to at least partially cure the conductive paste disposed in the vias 302. After the B-stage cure, the wafer 100 may be diced into individual die pieces. After separating the dice 102, 104, and 106 into individual die pieces, the individual die pieces may be attached to their respective underlying substrates (e.g., underlying carrier substrates) without having to add additional conductive paste onto the surface of their respective underlying substrates.

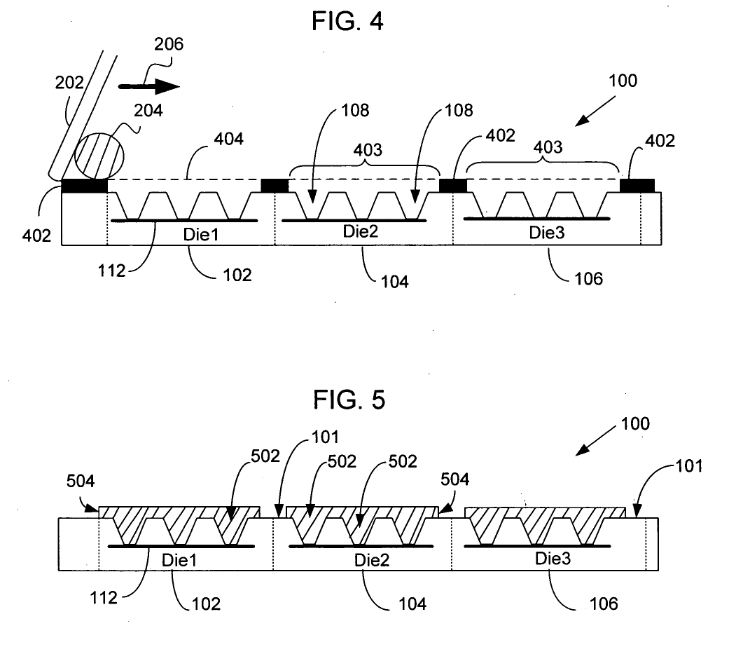

In some embodiments, a second process may be employed in which a screen or a stencil along with a squeegee may be used in order to fill via holes located on the backside surfaces of a die or dice prior to attaching the die or dice to their respective underlying substrates. Referring to FIG. 4 depicting a screen 402 having multiple openings 403 on top of a wafer 100, in accordance with various embodiments. As before, the wafer 100 having multiple backside via holes 108 that may be formed using various etching techniques. As depicted, the screen 402 may have corresponding openings 403 for each of the dice 102, 104, and 106, or alternatively, may include only a single opening that covers nearly the entire wafer 100. In some embodiments, the screen 402 may be a 0.5 to 3.0 millimeter stencil spacing (SS) screen. Again, a squeegee 202 may be employed in order to print or dispense conductive paste 204 into the via holes 108. In order to print the conductive paste 204 into the via holes 108, the squeegee 202 may be dragged along the top surface of the screen 402 to force the conductive paste 204 into the openings 403 of the screen 402 forcing the conductive paste 204 into the via holes 108. The conductive paste 204 may fill the openings 403 of the screen 402 at least up to a fill line 404.

Once the openings 403 of the screen 402 have been filled with the conductive paste 204, the screen 402 may be lifted from the backside surfaces of the dice 102, 104, and 106 leaving behind filled vias 502 and an extra layer 504 of conductive paste on top of the backside surfaces 101 of the dice 102, 104, and 106 as depicted in FIG. 5, in accordance with various embodiments. The extra layer 504 of conductive paste may subsequently facilitate the attachment of the dice 102, 104, and 106 to their respective underlying substrates without needing to add additional conductive paste or conductive adhesive film between the dice 102, 104, and 106 and their respective underlying substrates.

After the screen 402 has been removed, B-stage curing of the conductive paste in the vias 502 as well as the extra layer 504 of conductive paste on the backside surfaces 101 of the dice 102, 104, and 106 may be performed. The dice 102, 104, and 106 may then be singulated. Each of the individual die pieces may then be attached to their respective underlying substrates using, for example, the extra layer 504 of conductive paste to facilitate the attachments. In alternative embodiments, however, a thin film adhesive or additional conductive paste may be dispensed between each of the individual die pieces and their respective underlying substrates to facilitate the attachment of the individual die pieces to their respective underlying substrates.

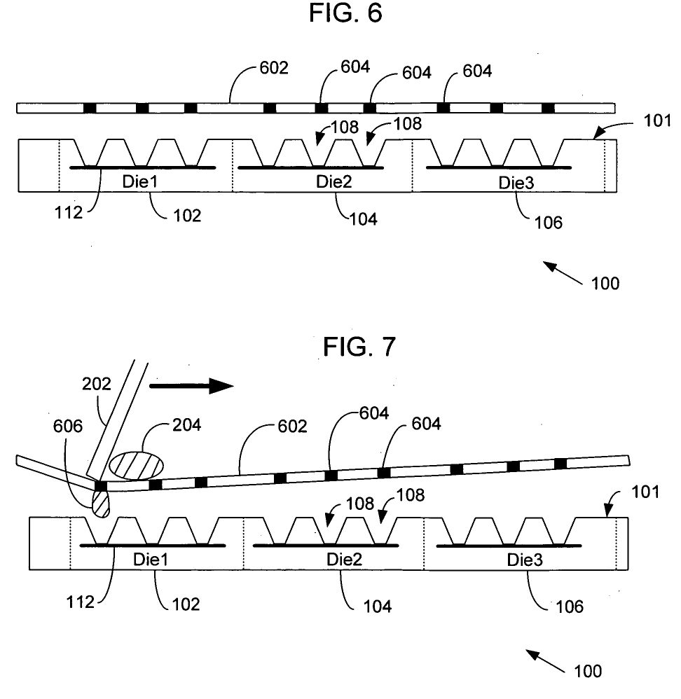

In some embodiments, a third process may be employed in which again a screen along with a squeegee is used in order to fill via holes located on the backside surfaces of a die or dice prior to attaching the die or dice to their respective underlying substrates. However, in the third process the screen is not placed directly on the wafer but instead, placed a slight distance above the backside surface of the wafer. FIG. 6 depicts a screen 602 placed a slight distance above the backside surfaces 101 of the dice 102, 104, and 106 in accordance with various embodiments. The screen 602 may be a flexible screen that may include a plurality of openings 604, each opening 604 corresponding to each of the via holes 108. When the screen 602 is positioned over the wafer 100, the openings 604 of the screen 602 may be precisely aligned over the via holes 108 by optical means.

FIG. 7 depicts a squeegee 202 and conductive paste 204 on top of the screen 602 in accordance with various embodiments. The squeegee 202 is moved or dragged across the top of the screen 602 forcing the conductive paste 204 into the openings 604 of the screen 602. Droplets 606 of conductive paste are then ejected through the openings 604 and into the via holes 108. The amount of conductive paste dispensed through the openings 604 may be a property of the viscosity of the conductive paste 204, the print speed (i.e., speed of the squeegee 202 across screen 602), as well as the size of the openings 604. In some embodiments, the openings 604 may be smaller than the size of the via hole openings to better control the amount of conductive paste 204 to be ejected into the via holes 108.

Once each of the via holes 108 has been filled with the conductive paste, B-stage curing may be performed in order to at least partially cure the conductive paste disposed in the via holes 108. After curing, the wafer 100 may be diced into individual die pieces. Each of the individual die pieces may then be attached to their respective underlying substrate at least in part by dispensing conductive paste onto the underlying substrate. Alternatively, the backside surface 101 of the wafer 100 may be laminated with a thin film adhesive prior to dicing the wafer 100. The wafer 100 may then be diced into individual die pieces (i.e., dice 102, 104, and 106). Each of the individual die pieces may then be attached to their respective underlying substrate without adding additional conductive paste to the surface of the underlying substrate.

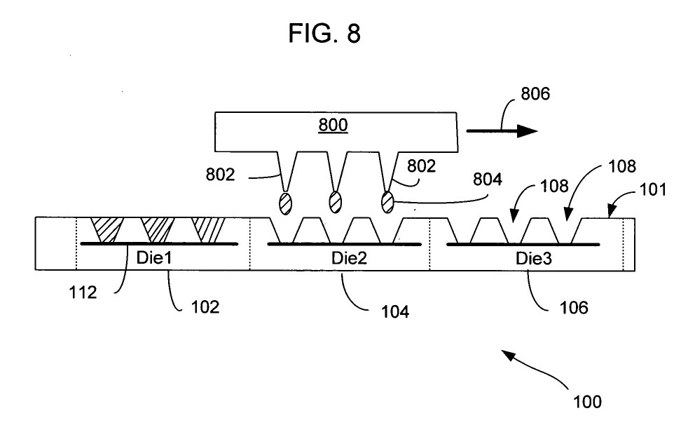

In some embodiments, a fourth process may be employed in which a dispensing device is used in order to fill via holes located on the backside surfaces of a die or dice prior to attaching the die or dice to their respective underlying substrates. FIG. 8 depicts a dispensing device 800 placed over a wafer 100 to fill the via holes 108 located on the backside surfaces 101 of the dice 102, 104, and 106, in accordance with various embodiments. For these embodiments, the dispensing device 800 comprises a plurality of micro dispensing needles 802 used to eject conductive paste 804. In some embodiments, the dispensing device 800 may be controlled by an electronic controller to selectively dispense controlled amounts of conductive paste into the via holes 108 as well as to control the movement of the dispensing device 800. For example, each of the micro dispensing needles 802 may be selectively extended or retracted at the point of conductive paste dispensing to match the via hole pattern below the dispensing device 800. In some embodiments, the via hole pattern and locations of the via holes of each die unit (i.e., dice 102, 104, and 106) may be preprogrammed. A pattern recognition component may be employed to align the micro dispensing needles 802 over the via holes 108.

In order to fill each of the via holes 108 with the conductive paste 804, the dispensing device 800 may be successively moved to different locations located over different portions of the wafer 100. For example, in order to fill each of the via holes 108 of the wafer 100, the dispensing device 800, along with its micro dispensing needles 802, may be initially positioned and aligned over a first subset of via holes. After being properly aligned over the first subset of via holes, the micro dispensing needles 802 may dispense controlled amounts of conductive paste into the first subset of via holes. Once the first subset of via holes are filled, the dispensing device 800 and its micro dispensing needles 802 may then be relocated over a second subset of via holes in order to fill the second subset of via holes. The micro dispensing needles 802 may be precisely aligned over the second subset of via holes using, for example, the pattern recognition component. The dispensing device 800 may then be successively relocated and realigned over different sets of via holes again and again over different portions of the wafer 100 as indicated by reference 806 until each of the via holes 108 on the wafer 100 has been filled. Note that although reference 806 indicates movement from left to right, in alternative embodiments, the dispensing device 800 may be moved from right to left or other directions.

Each of the above described illustrative processes allows for the manufacture and formation of a semiconductor package comprising one or more dice with backside vias having relatively low amounts of air voids. In particular, these processes may allow for the formation of a semiconductor package that includes one or more dice that are coupled to an underlying substrate, the one or more dice having a plurality of via holes etched into their backside surfaces. In some embodiments, the one or more dice being silicon or silicon compound dice such as SiBP dice. Alternatively, these processes may also be applied to other types of materials such as GaAs, InP, and so forth. The plurality of via holes, which may be ground through silicon vias, may be substantially pyramidal or conical in shape, decreasing from a wider end to a narrower end as the via hole advances through the backside surface, and each of the via holes being capped at the narrower end and having been filled with conductive paste trapping an air void with a volume of not larger than 8% of the via holes. Note that in alternative embodiments, the via holes may have other shape types such as cylindrical types of shape. Each of these one or more dice being attached to the underlying substrate through their backside surfaces. The underlying substrate, in some embodiments, may be an underlying carrier substrate, such as Cu leadframe or BT substrate.

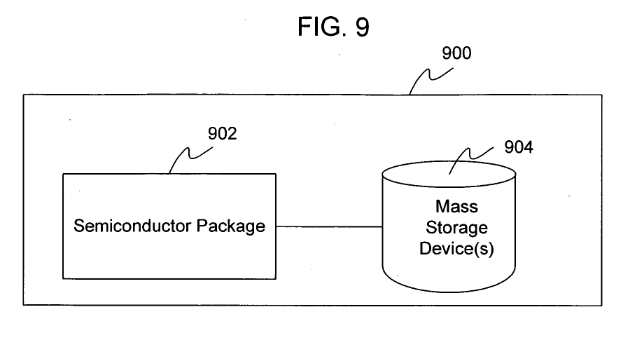

FIG. 9 depicts a system in accordance with various embodiments of the present invention. The system 900 comprises semiconductor package 902 and mass storage device(s) 904, coupled together as shown. The semiconductor package 902 may include one or more dice coupled to an underlying carrier substrate, the one or more dice having backside vias with relatively low amounts of air voids as previously described.

In various embodiments, the mass storage device(s) 904 and the semiconductor package 902 (except for the teachings of embodiments of the invention incorporated therein) represent a broad range of elements known in the art. For example, the mass storage device(s) 904 may include optical storage, magnetic storage such as disk drive, and so forth. Further, system 900 may be embodied in a broad range of form factors for a broad range of general or special purpose applications including, for example, a wireless adaptor, a wireless mobile phone, a set-top box, a personal digital assistant, a tablet computing device, a desktop computing device, a laptop computing device, and/or an entertainment control unit. System 900 may be endowed with various operating systems and/or applications to solve various computing problems.

Although the foregoing discussion has described particular embodiments, it will be appreciated by those of ordinary skill in the art that a wide variety of alternate and/or equivalent embodiments or implementations calculated to achieve the same or similar purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

What is claimed is:

1. A method, comprising:
forming one or more via holes on a backside surface of each of a plurality of dice formed on a wafer, said forming being performed prior to the dice being singulated;
depositing conductive paste into the one or more via holes of each of the plurality of dice from a direction above the backside surface of each of the dice, said depositing being also performed prior to the dice being singulated;
singulating the dice; and
attaching each of the dice to one or more underlying carrier substrates.

2. The method of claim 1, wherein said forming comprises forming each of the via holes with a pyramidal or conical shape, and said depositing comprises depositing conductive paste into the via holes having the pyramidal or conical shapes.

3. The method of claim 1, wherein said depositing comprises using a squeegee to force the conductive paste into the via holes.

4. The method of claim 3, wherein said using of a squeegee to force the conductive paste into the via holes comprises using a squeegee to force the conductive paste into the via holes through a screen having a plurality of openings.

5. The method of claim 4, wherein the method further comprises placing the screen over the backside surface of each of the dice, with the openings of the screen aligned with the via holes.

6. The method of claim 5, wherein the method further comprises placing the screen at a distance above the backside surface of each of the dice.

7. The method of claim 5, wherein said placing comprises optically aligning the openings of the screen with the via holes.

8. The method of claim 1, wherein said depositing comprises dispensing the conductive paste into the via holes from a dispensing device having a plurality of micro dispensing needles, a subset of the via holes at a time.

9. The method of claim 8, wherein the method further comprises successively aligning the dispensing device over the plurality of subsets of the via holes, one subset at a time.

10. The method of claim 9, wherein said successive aligning comprises recognizing each subset of the via holes with a pattern recognition component.

11. The method of claim 1, further comprising laminating a conductive adhesive film to the wafer prior to singulating the dice.

12. The method of claim 1, further comprising curing the conductive paste prior to singulating the dice, and dispensing additional conductive paste onto a surface of an underlying carrier substrate prior to attaching the underlying carrier substrate to a die.

13. A semiconductor package, comprising
a die having a backside surface and a plurality of via holes etched into the backside surface, each of the via holes being substantially pyramidal or conical in shape decreasing from a wider end to a narrower end as the via hole advances through the backside surface, and each of the via holes being capped at the narrower end and having been filled with conductive paste trapping an air void with a volume of not larger than 8 percent of the via holes; and
an underlying carrier substrate attached the to die at the backside surface.

14. The semiconductor package of claim 13, wherein each of via holes has a wider end of about 400 μm and a narrower end of about 50 μm.

15. The semiconductor package of claim 13 wherein the die is a silicon backplane (SiBP) die.

16. The semiconductor package of claim 13 wherein the die is a silicon or silicon compound die, and the via holes are ground through silicon vias.

17. The semiconductor package of claim 13 further comprising one or more metal caps correspondingly capping the via holes.

18. The semiconductor package of claim 13 wherein the carrier substrate is a copper based substrate.

19. A system, comprising:
a semiconductor package having:
a die having a backside surface and a plurality of via holes etched into the backside surface, each of the via holes being substantially pyramidal or conical in shape decreasing from a wider end to a narrower end as the via hole advances through the backside surface, and each of the via holes being capped at the narrower end and having been filled with conductive paste trapping an air void with a volume of not larger than 8 percent of the via holes; and
an underlying carrier substrate attached to the die at the backside surface; and
one or more mass storage devices coupled to the semiconductor package.

20. The system of claim 19, wherein each of the via holes has a wider end of about 400 μm and a narrower end of about 50 μm.

21. The system of claim 19, wherein the die is a silicon backplane (SiBP) die.

22. The system of claim 19, wherein the system is a selected one of a wireless adaptor, a wireless mobile phone, a set-top box, a personal digital assistant, a tablet computing device, a laptop computing device, a desktop computing device, or an entertainment control unit.
